(19) United States
(12) Patent Application Publication
(10) Pub. No.: US 2017/0350949 A1
(43) Pub. Date: Dec. 7, 2017

(54) COMPONENTS ON FLEXIBLE SUBSTRATES AND METHOD FOR THE PRODUCTION THEREOF

(71) Applicant: LEIBNIZ-INSTITUT FUER FESTKOERPER-UND WERKSTOFFFORSCHUNG DRESDEN E.V, Dresden (DE)

(72) Inventors: Ingolf MOENCH, Freital (DE); Denys MAKAROV, Dresden (DE); Oliver G. SCHMIDT, Dresden (DE)

(73) Assignee: LEIBNIZ-INSTITUT FUER FESTKOERPER-UND WERKSTOFFFORSCHUNG DRESDEN E.V, Dresden (DE)

(21) Appl. No.: 15/609,631

(22) Filed: May 31, 2017

(30) Foreign Application Priority Data
Jun. 1, 2016 (DE) 10 2016 209 518.8

(51) Int. Cl. G01R 33/09; H01F 1/03; C23C 14/18; C23C 14/04; C23C 14/08

(52) U.S. Cl. CPC G01R 33/093; H01F 1/0306; C23C 14/081; C23C 14/042; C23C 14/18

(57) ABSTRACT

The invention concerns the field of electronics and materials science and relates to components on flexible substrates, as are for example used as sensors or actuators in the automotive industry, mechanical engineering or electronics, and to a method for the production thereof.

The object of the present invention is the specification of components on flexible substrates, the physical and in particular electrical properties of which have long-term stability, and the specification of a cost-efficient and simple method for the production thereof.

The object is attained with components on flexible substrates, composed of a flexible substrate having a barrier layer arranged at least partially thereon, on which layer a components layer is at least partially positioned.

### CROSS-REFERENCE TO RELATED APPLICATIONS

The present application claims priority under 35 U.S.C. §119 of German Patent Application No. 10 2016 209 518.8, filed Jun. 1, 2016, the disclosure of which is expressly incorporated by reference herein in its entirety.

The invention concerns the field of electronics and materials science and relates to components on flexible substrates, as are for example used as sensors or actuators in the automotive industry, mechanical engineering or electronics, and to a method for the production thereof.

Sensors on flexible substrates are being used to a constantly increasing degree in technology. As substrate materials, films selected according to the specific application case are used. Often, polyimide films or polyether ether ketone films are used because of the suitable chemical and physical properties thereof. Polyimide films of this type are, among other things, known by the trade name Kapton®. Polyimide is a very chemically stable and temperature-stable substrate material that can be produced with established industrial methods and with known thin-layer technology methods. For example, films of this type can be coated by means of sputtering and subsequently structured, and sensors can thus be fabricated.

A major field of application for this type of components on flexible substrates is magnetic field sensors, in particular based on bismuth. These sensors have the advantage that they exhibit a linear characteristic curve over a large magnetic field range and have a sensitivity perpendicular to the layer plane.

According to DE 10 2011 087 342 A1, the use of flexible magnetic thin-layer sensor elements on non-planar surfaces in the air gap of electromagnetic energy converters and magnetomechanical energy converters is known, with which sensor elements magnetic fields in the air gap can be measured.

Furthermore, elastic optoelectronic (Kim et al.: Nature Mater. 2010, 9, 929-937), elastic magnetic (M. Melzer et al.: Nano Letters 2011, 11, 2522-2526) and elastic electronic components (Kim et al.: Nature Mater. 2011, 10, 316-323) are specifically known. Likewise, bismuth Hall effect sensors on a flexible substrate such as for example polyimide films or polyether ether ketone films are known (M. Melzer et al.: Adv. Mater. 27, 1274 (2015); I. Winch et al.: IEEE Trans. Magn. 51, 4004004 (2015)).

According to DE 199 29 864 A1, sensors for the non-contact measurement of torques are also known. The sensor, which is based on the magnetostrictive principle, uses an IC in which coils, a ferromagnetic yoke, magnetically sensitive components and optional signal processing circuits are integrated. Ferromagnetic strips conduct the magnetic flux directly to the magnetically sensitive components on the IC. The ferromagnetic strips absorb the flux over a large area and optionally at multiple measuring points on the shaft circumference.

A disadvantage with the solutions from the prior art for components on flexible substrates is that a long-term stability of the physical properties thereof is frequently not achieved under application conditions, and that production of these components is often expensive.

The object of the present invention is the specification of components on flexible substrates, the physical and in particular electrical properties of which have long-term stability, and the specification of a cost-efficient and simple method for the production thereof.

The object is attained by the invention disclosed in the claims. Advantageous embodiments are the subject matter of the dependent claims.

The components on flexible substrates according to the invention are composed of a flexible substrate having a barrier layer arranged at least partially thereon, on which layer a components layer is at least partially positioned.

Advantageously, films or thin layers are present as flexible substrate, wherein more advantageously films or thin layers of polyimide are present.

Also advantageously, electrically insulating layers are present as barrier layers, wherein more advantageously layers of aluminum oxide and/or silicon dioxide are present as barrier layers.

Likewise advantageously, layers of bismuth or bismuth-based magnetically sensitive alloys are present as a components-layer.

And also advantageously, the barrier layer fully covers the flexible substrate and/or is structured.

It is also advantageous if the components layer is arranged solely on the barrier layer.

It is likewise advantageous if the components layer fully covers the barrier layer and/or is arranged thereon in a structured manner.

And it is also advantageous if the barrier layer fully covers and envelops the components layer.

In the method according to the invention for the production of components on flexible substrates, a barrier layer is at least partially applied to a flexible substrate using thin layer technologies, and a components layer is at least partially applied to the barrier layer.

With the present invention, components on flexible substrates are for the first time achieved, the physical and in particular electrical properties of which have long-term stability, and which components can be produced with a cost-effective and simple method.

This is achieved with components that are composed of a flexible substrate. A barrier layer is at least partially positioned on the substrate, and a components layer is then at least partially positioned thereon.

Films or thin layers can be present as a flexible substrate, for example, films or thin layers of polyimide. On the flexible substrate, a barrier layer is at least partially arranged thereon according to the invention. Electrically insulating layers can advantageously be present as a barrier layer, such as layers of aluminum oxide and/or silicon dioxide, for example. Furthermore, a components layer is at least partially positioned on the barrier layer. Advantageously, layers of bismuth or bismuth-based magnetically sensitive alloys can be present as a components layer.

Also advantageously, the barrier layer can fully cover the flexible substrate and/or be arranged in a structural manner and/or the components layer can fully cover the barrier layer and/or be arranged in a structured manner. A structured arrangement can thereby occur in the form of functional regions or shapes, and can be achieved for example by application with a mask.

Advantageously, the components layer is arranged solely on the barrier layer. Likewise advantageously, the components layer is fully covered by the barrier layer.

In the case of magnetic field sensors as components according to the invention, a film of polyimide is advantageously used as a flexible substrate, on which film a thin layer of aluminum oxide is arranged as a barrier layer and a thin layer of bismuth is arranged as a components layer. The barrier layer is arranged with the entire area thereof on the film or has been applied in a structured manner to the substrate using a mask. The bismuth layer is positioned solely on the barrier layer and can in this location also be arranged in a structured manner using a mask. Advantageously, the bismuth layer is also fully enveloped by the barrier layer of aluminum oxide.

Typically, magnetic field sensors and in particular magnetic field sensors based on bismuth have, with regard to the magnetic properties thereof, a linear characteristic curve over a large magnetic field range. However, it has been shown that the electrical properties do not have long-term stability under application conditions. For example, the electrical resistance of a bismuth layer on a Kapton® film under storage in air for 1500 hours at 120° C. changes by up to 80%. This leads to an irreparable change in the characteristic values all the way up to a complete failure of the components.

It was assumed that oxidation processes of the bismuth layers are possibly responsible therefor, as polyimide in particular is very chemically stable as a substrate material and is for this reason widely used in microelectronics. Accordingly, in order to prevent undesired effects of this kind, covering layers were applied to the bismuth layers and components composed thereof in the prior art. Surprisingly, however, it was shown that it was not possible to improve the long-term stability of the sensors by doing so.

In separate analyses, it was possible to determine that diffusion processes clearly do, in fact, occur between the substrate material and the components-layer material, which processes result in these marked changes in the properties of the components when the components are used for longer periods. Accordingly, it was proposed according to the invention that a barrier layer be arranged between the substrate material and components material to prevent diffusion processes of this type between these two materials. At the same time, however, it must also be ensured that the flexibility of the entire component and the substrate is not significantly impaired by the additional layers, which is why the barrier layers are also present in the form of thin layers or films and can be produced using thin layer technologies.

Aluminum oxide layers with layer thicknesses for example in the range of 5 to 100 nm and for example deposited by means of the atomic layer deposition (ALD) method can be used for magnetic field sensors in regard to both their barrier effect and also their flexibility. They are also mechanically stable at bending radii minimally up to 2 mm, and the magnetic field sensors on Kapton® films, which sensors are produced with an aluminum oxide layer of this type, also do not exhibit any changes in the values for the electrical resistance as part of the measurement accuracy after storage in air for 5000 hours at 120° C.

A further improvement in the long-term stability can also be achieved in that protective layers are applied to the components layers, which are often also mechanically sensitive. For example, protective layers of the flexible substrate material, as is known from the prior art, or protective layers of the barrier-layer material, according to the invention, can be applied for this purpose. In both cases, the components layer is positioned on the mechanically neutral plane of the entire component, and the components layer is thus both protected with regard to the deterioration of the long-term stability of properties of the component and also optimized with regard to mechanical tensions that occur.

The invention is explained below in greater detail with the aid of an exemplary embodiment.

### EXAMPLE 1

A 10-nm thick Al₂O₃ layer was applied over the entire area to a polyimide film with the dimensions 100 mm×50 mm×0.1 mm (L×W×H). For this purpose, the coating chamber was evacuated to a residual gas pressure of 2×10⁻⁶ mbar. The coating took place at 120° C. with the use of TMAl(trimethylaluminum) as a precursor and water as a reducing agent (t=100 ms). At a total of 125 cycles, 10 nm Al₂O₃ was obtained. The time between 2 cycles was set at 4000 ms. A 250-nm thick Bi layer was subsequently deposited on the Al₂O₃-coated substrate by means of high-frequency sputtering. To do so, the coating system was evacuated to a residual gas pressure of 4×10⁻⁷ mbar. Argon was then introduced as a sputtering gas to a partial pressure of 1×10⁻³ mbar, and the high-frequency plasma was ignited. The Bi coating was performed at an output power of 50 W and a deposition rate of 14 nm/min. The coating took place through a metallic vapor penetration mask so that an additional geometric structuring was not necessary. The sensor was composed of the actual Hall cross and the necessary supply lines and connection contacts. For an improved contact capability, a solderable contact and soldering layer was applied at the ends of the conductor tracks. This coating took place by means of electron beam evaporation. For this purpose, a metallic vapor penetration mask was placed on the Bi-coated Kapton substrate provided with Al₂O₃, wherein the openings in the vapor penetration mask defined the shape and the lateral size of the subsequent contact regions. After the evacuation of the coating chamber, a 5-nm thick Cr adhesive layer (coating rate=0.1 nm/s) was first applied and then a 100-nm thick Au layer (coating rate=0.2 nm/s) by means of electron beam evaporation. The starting vacuum was 1×10⁻⁷ mbar. The contact layers produced in this manner showed excellent solderability and were able to be used to connect the sensor to the electrical measuring devices.

This component was flexible and could, for example, be bonded in place in bearings of electric motors. After storage in air for 5000 hours at 120° C., it was possible to verify the long-term stability, since no changes occurred in the values for the electrical resistance as part of the measurement accuracy.

1. Components on flexible substrates, composed of a flexible substrate having a barrier layer arranged at least partially thereon, on which layer a components layer is at least partially positioned.

2. The components according to claim 1 in which films or thin layers are present as a flexible substrate.

3. The components according to claim 2 in which films or thin layers of polyimide or polyether ether ketone are present.

4. The components according to claim 1 in which electrically insulating layers are present as barrier layers, which prevent to the greatest possible extent the diffusion process between the substrate and the components layers.

5. The components according to claim 4 in which layers of aluminum oxide and/or silicon dioxide are present as barrier layers.

6. The components according to claim 1 in which layers of bismuth or bismuth-based alloys are present as components layers.

7. The components according to claim 1 in which the barrier layer fully covers the flexible substrate and/or is structured.

8. The components according to claim 1 in which the components layer is arranged solely on the barrier layer.

9. The components according to claim 1 in which the components layer fully covers the barrier layer and/or is arranged thereon in a structured manner.

10. The components according to claim 1 in which the barrier layer fully covers and envelops the components layer.

11. A method for the production of components on flexible substrates in which a barrier layer is applied at least partially to a flexible substrate using thin layer technologies and a components layer is applied at least partially to the barrier layer.
